(19) United States
(12) Patent Application Publication
(10) Pub. No.: US 2019/0123242 A1
(43) Pub. Date: Apr. 25, 2019

(54) LIGHT EMITTING APPARATUS

(71) Applicant: Au Optronics Corporation, Hsinchu (TW)

(72) Inventors: Tzu-Yi Tsao, Taipei City (TW); Cheng-Yeh Tsai, Taipei City (TW)

(73) Assignee: Au Optronics Corporation, Hsinchu (TW)

(21) Appl. No.: 15/910,024

(22) Filed: Mar. 2, 2018

(30) Foreign Application Priority Data
Oct. 19, 2017 (TW) 106135876

(51) Int. Cl. H01L 33/38; H01L 33/06; H01L 33/32; H01L 33/40; H01L 33/44; H01L 33/62; H01L 25/07; H01L 27/12; H01L 33/00

(52) U.S. Cl. CPC H01L 33/385; H01L 33/06; H01L 33/32; H01L 33/405; H01L 33/44; H01L 2933/0066; H01L 25/071; H01L 27/1214; H01L 33/0079; H01L 2933/0025; H01L 2933/0016; H01L 33/62

(57) ABSTRACT

A light emitting apparatus including a first semiconductor layer, a light emitting layer, a second semiconductor layer, an insulation layer, a first electrode and a second electrode is provided. The light emitting layer is disposed on the first semiconductor layer. The second semiconductor layer is disposed on the light emitting layer. The insulation layer is at least disposed on a side wall of the first semiconductor layer. The first electrode is disposed on a bottom surface of the first semiconductor layer and at least one portion of the insulation layer. The second electrode is disposed on the second semiconductor layer.

### CROSS-REFERENCE TO RELATED APPLICATION

This application claims the priority benefit of Taiwan application serial no. 106135876, filed on Oct. 19, 2017. The entirety of the above-mentioned patent application is hereby incorporated by reference herein and made a part of this specification.

### BACKGROUND

### Technical Field

The disclosure relates to a light emitting apparatus.

### Description of Related Art

As technology advances, a light emitting diode (LED) has already become a common device widely used in various fields. As a light source, the light emitting diode has a lot of advantages, such as low power consumption, long lifetime, and fast switching speed. Therefore, the traditional light source has been gradually replaced by the light emitting diode.

Besides serving as the light source, the light emitting diode has also been applied in the display field. For example, a micro-LED display apparatus using micro-light emitting diodes as pixels has already been developed in recent years. However, in comparison to the traditional light emitting diode, the micro-light emitting diode has a smaller area of the light emitting surface. Since the area of the light emitting surface of the micro-light emitting diode is smaller, light extraction efficiency of the micro-light emitting diode becomes lower as well. In other words, the micro-light emitting diode has a problem of insufficient brightness. Accordingly, how to effectively address the foregoing problem has become a goal that needs to be attained in the current field.

### SUMMARY

The disclosure provides a light emitting apparatus with good performance.

The light emitting apparatus of this disclosure includes a first semiconductor layer, a light emitting layer, a second semiconductor layer, an insulation layer, a first electrode, and a second electrode. The light emitting layer is disposed on the first semiconductor layer. The second semiconductor layer is disposed on the light emitting layer. The light emitting layer has a bottom surface, a top surface, and a side wall. The side wall of the light emitting layer is connected between the bottom surface of the light emitting layer and the top surface of the light emitting layer. The first semiconductor layer has a bottom surface, a top surface, and a side wall. The side wall of the first semiconductor layer is connected between the bottom surface of the first semiconductor layer and the top surface of the first semiconductor layer. The top surface of the first semiconductor layer is disposed between the bottom surface of the first semiconductor layer and the bottom surface of the light emitting layer. The insulation layer is at least disposed on the side wall of the first semiconductor layer. The first electrode is disposed on the bottom surface of the first semiconductor layer and at least one portion of the insulation layer, wherein the first electrode covers at least one portion of the side wall of the first semiconductor layer. The second electrode is disposed on the second semiconductor layer.

Based on the foregoing, the light emitting apparatus according to an embodiment of the disclosure uses the first electrode to reflect the light beam emitted by the light emitting layer, so that the light beam is emitted from the top surface (i.e., the front) of the second semiconductor layer. Accordingly, light extraction efficiency and/or brightness of the light emitting apparatus are enhanced.

To make the foregoing features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A through 1E are schematic cross-sectional views illustrating a process of manufacturing a light emitting apparatus according to an embodiment of the disclosure.

FIG. 2 is a schematic top view of the light emitting diode of FIG. 1E.

FIG. 3 is a schematic cross-sectional view of a light emitting apparatus according to another embodiment of the disclosure.

FIG. 4 is a schematic cross-sectional view of a light emitting apparatus according to another embodiment of the disclosure.

FIG. 5 is a schematic cross-sectional view of a light emitting apparatus according to another embodiment of the disclosure.

### DESCRIPTION OF THE EMBODIMENTS

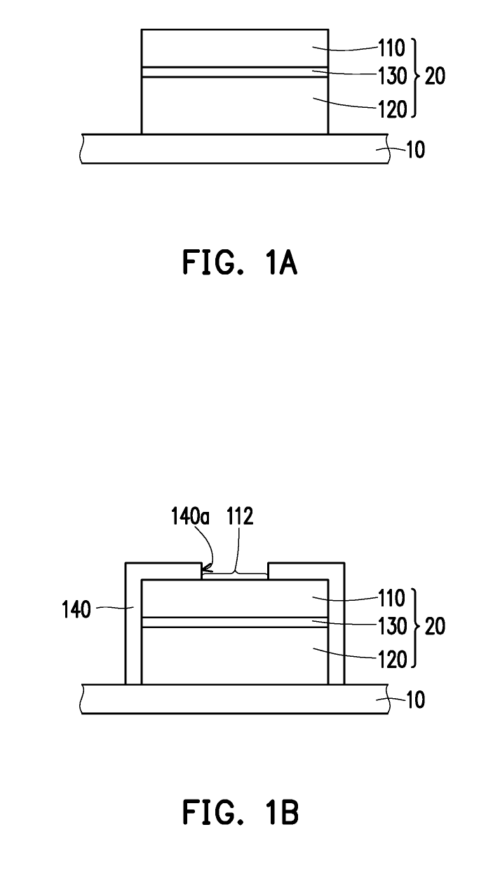

FIGS. 1A through 1E are schematic cross-sectional views illustrating a process of manufacturing a light emitting apparatus according to an embodiment of the disclosure. Firstly, with reference to FIG. 1A, a growth substrate 10 is provided. In this embodiment, the growth substrate 10 is, for example, a sapphire substrate, but the disclosure is not limited thereto. Then, a semiconductor stacking layer 20 is formed on the growth substrate 10. The semiconductor stacking layer 20 includes a first semiconductor layer 110, a second semiconductor layer 120, and a light emitting layer 130 located between the first semiconductor layer 110 and the second semiconductor layer 120. For example, in this embodiment, the first semiconductor layer 110 includes a P-type semiconductor layer (such as P—GaN), the second semiconductor layer 120 includes an N-type semiconductor layer (such as N—GaN), and the light emitting layer 130 includes a multiple quantum well (MQW) structure. However, the disclosure is not limited thereto.

Then, with reference to FIG. 1B, an insulation layer 140 is formed on the growth substrate 10 to partially cover the semiconductor stacking layer 20. For example, in this embodiment, the insulation layer 140 has a contact hole 140a to expose an electrical connection area 112 of the first semiconductor layer 110. In this embodiment, the insulation layer 140 is light-transmissive. A material of the insulation layer 140 may be an inorganic material (e.g., silicon oxide, silicon nitride, silicon oxynitride, or a stack layer of at least two of the foregoing materials), an organic material, or a combination of the foregoing.

Next, with reference to FIG. 1C, a first electrode 150 is formed on the insulation layer 140. In this embodiment, the first electrode 150 may selectively cover the insulation layer 140 completely, but the disclosure is not limited thereto. In this embodiment, the first electrode 150 may be filled in the contact hole 140a of the insulation layer 140 to cover the electrical connection area 112 of the first semiconductor layer 110 and be electrically connected to the first semiconductor layer 110. A material of the first electrode 150 is reflective and conductive. For example, in this embodiment, the material of the first electrode 150 is metal, but the disclosure is not limited thereto. In other embodiments, the first electrode 150 may also be formed of other conductive materials, such as an alloy, a nitride of the metal material, an oxide of the metal material, a nitrogen oxide of the metal material, graphene, a stack layer of the metal material, or a stack layer of other conductive materials.

Then, with reference to FIGS. 1C and 1D, the growth substrate 10 is removed to expose a top surface 120a of the second semiconductor layer 120, and the semiconductor stacking layer 20, the insulation layer 140 and the first electrode 150 are transferred onto an active device substrate 160. For example, as shown in FIG. 1D, in this embodiment, the semiconductor stacking layer 20, the insulation layer 140 and the first electrode 150 are fixed on the active device substrate 160 by a bonding layer 170. In this embodiment, the bonding layer 170 is, for example, an insulating adhesive layer. However, the disclosure is not limited thereto. In other embodiments, the semiconductor stacking layer 20, the insulation layer 140 and the first electrode 150 may also be fixed on the active device substrate 160 by other suitable components. For example, in another embodiment, the first electrode 150, the insulation layer 140 and the semiconductor stacking layer 20 may also be fixed on the active device substrate 160 by a conductive paste (not shown).

Then, with reference to FIG. 1E, a second electrode 180 is formed on a portion of the top surface 120a of the second semiconductor layer 120. The second electrode 180 and the second semiconductor layer 120 are electrically connected to each other. The second electrode 180, the semiconductor stacking layer 20, the insulation layer 140 and the first electrode 150 may be called a light emitting diode (LED). In this embodiment, the active device substrate 160 is, for example, a pixel array substrate including components such as a plurality of thin film transistors, a plurality of data lines electrically connected to sources of the thin film transistors, and a plurality of scan lines electrically connected to gates of the thin film transistors. The pixel array substrate has a plurality of pixel regions, and the number of the light emitting diodes (LEDs) disposed on each pixel region may be determined on actual requirements. The numbers of the light emitting diodes (LEDs) disposed on the pixel regions respectively may be the same as or different from one another, and the disclosure is not limited thereto. In this embodiment, the second electrode 180 may be a transparent electrode, a reflective electrode, or a combination thereof. For example, a material of the transparent electrode may be a metal oxide such as indium tin oxide, indium zinc oxide, aluminum tin oxide, aluminum zinc oxide, indium germanium zinc oxide, or other suitable oxides, or a stack layer including at least two of the foregoing. A material of the reflective electrode may be metal or other suitable materials. However, the disclosure is not limited thereto.

In this embodiment, when the second electrode 180 is formed, a conductive pattern 190 may be formed simultaneously. The first electrode 150 may be electrically connected to the active device substrate 160 through the conductive pattern 190. The conductive pattern 190 and the second electrode 180 may be made of the same material. In other words, the second electrode 180 and the conductive pattern 190 may be formed of the same conductive layer. At this point, the light emitting apparatus 100 of this embodiment is completed.

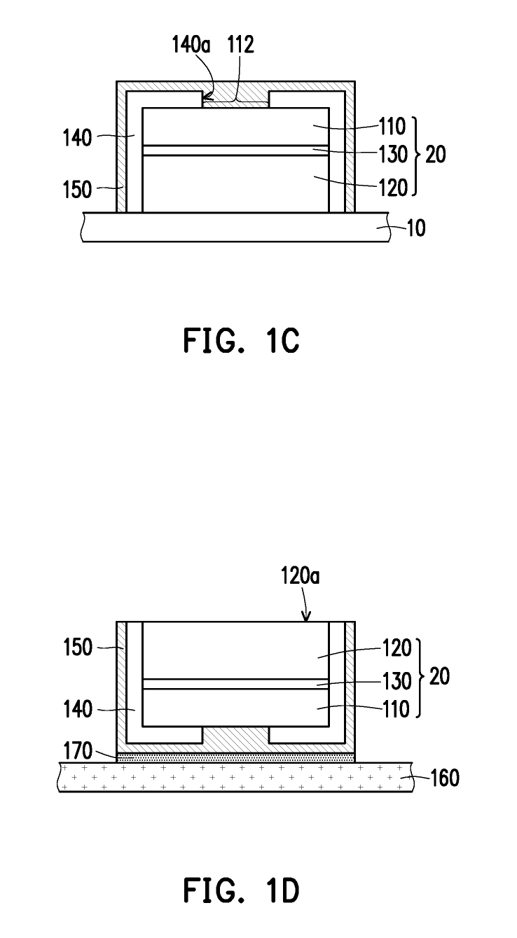

FIG. 2 is a schematic top view of the light emitting diode (LED) of FIG. 1E. FIG. 1E and FIG. 2 schematically illustrate a x-y-z coordinate system to facilitate understanding of the relative spatial relationship between the cross-sectional view of FIG. 1E and the top view of FIG. 2, wherein x, y and z directions are perpendicular to one another.

With reference to FIG. 1E and FIG. 2, the light emitting apparatus 100 includes the first semiconductor layer 110, the light emitting layer 130, the second semiconductor layer 120, the insulation layer 140, the first electrode 150, and the second electrode 180. The first semiconductor layer 110 has a bottom surface 110b, a top surface 110a, and a side wall 110c that is connected between the bottom surface 110b and the top surface 110a. The light emitting layer 130 is disposed on the first semiconductor layer 110. The light emitting layer 130 has a bottom surface 130b, a top surface 130a, and a side wall 130c that is connected between the bottom surface 130b and the top surface 130a. The top surface 110a of the first semiconductor layer 110 is disposed between the bottom surface 110b of the first semiconductor layer 110 and the bottom surface 130b of the light emitting layer 130. The second semiconductor layer 120 is disposed on the light emitting layer 130. The second semiconductor layer 120 has a bottom surface 120b, a top surface 120a, and a side wall 120c that is connected between the bottom surface 120b and the top surface 120a. The top surface 130a of the light emitting layer 130 is disposed between the bottom surface 130b of the light emitting layer 130 and the bottom surface 120b of the second semiconductor layer 120.

The insulation layer 140 is at least disposed on the side wall 110c of the first semiconductor layer 110. For example, in this embodiment, the insulation layer 140 may also be selectively disposed on a portion of the bottom surface 110b of the first semiconductor layer 110, the side wall 130c of the light emitting layer 130, and the side wall 120c of the second semiconductor layer 120, but the disclosure is not limited thereto. As shown in FIG. 1E and FIG. 2, the insulation layer 140 surrounds at least one portion of the side wall 110c of the first semiconductor layer 110. In the present specification, the expression “component A ‘surrounds’ component B” means that component A covers component B, and a normal projection of component A (e.g., the insulation layer 140) in the z direction forms a closed annular pattern and a normal projection of component B (e.g., the side wall 110c of the first semiconductor layer 110) is located within the closed annular pattern. In other words, if “component A covers component B” is referred to in the present specification, such reference does not limit that component A must surround component B. Component A that covers component B may surround or may not surround component B.

For example, with reference to FIG. 1E and FIG. 2, in this embodiment, the insulation layer 140 may surround the side wall 110c of the first semiconductor layer 110 and may selectively cover the side wall 110c of the first semiconductor layer 110 completely. However, the disclosure is not limited thereto. In other embodiments, the insulation layer 140 may surround the side wall 110c of the first semiconductor layer 110 to partially cover the side wall 110c of the first semiconductor layer 110 (such as covering the lower portion of the side wall 110c without covering the upper portion of the side wall 110c). In this embodiment, the insulation layer 140 may also surround the side wall 130c of the light emitting layer 130 and may selectively cover the side wall 130c of the light emitting layer 130 completely. However, the disclosure is not limited thereto. In other embodiments, the insulation layer 140 may surround the side wall 130c of the light emitting layer 130 to partially cover the side wall 130c of the light emitting layer 130 (such as covering the lower portion of the side wall 130c without covering the upper portion of the side wall 130c). In this embodiment, the insulation layer 140 may also surround the side wall 120c of the second semiconductor layer 120 and cover the side wall 120c of the second semiconductor layer 120 completely. However, the disclosure is not limited thereto. In other embodiments, the insulation layer 140 may surround the side wall 120c of the second semiconductor layer 120 to partially cover the side wall 120c of the second semiconductor layer 120 (such as covering the lower portion of the side wall 120c without covering the upper portion of the side wall 120c).

The first electrode 150 is disposed on the bottom surface 110b of the first semiconductor layer 110. The first electrode 150 is electrically connected to the first semiconductor layer 110. For example, in this embodiment, the insulation layer 140 partially covers the bottom surface 110b of the first semiconductor layer 110 and has the contact hole 140a located on the bottom surface 110b of the first semiconductor layer 110. The first electrode 150 is filled in the contact hole 140a of the insulation layer 140 to be electrically connected to the first semiconductor layer 110.

The first electrode 150 is disposed on at least one portion of the insulation layer 140. In this embodiment, the first electrode 150 surrounds at least one portion of the side wall 110c of the first semiconductor layer 110. In other words, as shown in FIG. 1E and FIG. 2, a vertical projection of the first electrode 150 forms a closed annular pattern in the z direction, and a vertical projection of the side wall 110c of the first semiconductor layer 110 is located inside the vertical projection of the first electrode 150 having a closed annular shape. For example, in this embodiment, the first electrode 150 may surround the side wall 110c of the first semiconductor layer 110 and may selectively cover the side wall 110c of the first semiconductor layer 110 completely. However, the disclosure is not limited thereto. In other embodiments, the first electrode 150 may surround the side wall 110c of the first semiconductor layer 110 to partially cover the side wall 110c of the first semiconductor layer 110 (such as covering the lower portion of the side wall 110c without covering the upper portion of the side wall 110c). In this embodiment, the first electrode 150 may also surround the side wall 130c of the light emitting layer 130 and may selectively cover the side wall 130c of the light emitting layer 130 completely. However, the disclosure is not limited thereto. In other embodiments, the first electrode 150 may surround the side wall 130c of the light emitting layer 130 to partially cover the side wall 130c of the light emitting layer 130 (such as covering the lower portion of the side wall 130c without covering the upper portion of the side wall 130c). In this embodiment, the first electrode 150 may also surround the side wall 120c of the second semiconductor layer 120 and cover the side wall 120c of the second semiconductor layer 120 completely. However, the disclosure is not limited thereto. In other embodiments, the first electrode 150 may surround the side wall 120c of the second semiconductor layer 120 to partially cover the side wall 120c of the second semiconductor layer 120 (such as covering the lower portion of the side wall 120c without covering the upper portion of the side wall 120c). In addition, in this embodiment, the first electrode 150 does not cover the top surface 120a of the second semiconductor layer 120 so as to be electrically isolated from the second semiconductor layer 120.

The second electrode 180 is disposed on the second semiconductor layer 120. To be more specific, the second electrode 180 is disposed on the top surface 120a of the second semiconductor layer 120 and electrically connected to the second semiconductor layer 120. In this embodiment, the light emitting apparatus 100 may further include the active device substrate 160 to form a micro-LED display apparatus. In this embodiment, the first electrode 150 may be electrically connected to the active device substrate 160. In detail, the first electrode 150 may be electrically connected to the active device substrate 160 through the conductive pattern 190. For example, the conductive pattern 190 may be connected to the first electrode 150, which is located on the side wall 110c of the first semiconductor layer 110, and to the active device substrate 160 simultaneously, and the first electrode 150 and the active device substrate 160 may be electrically connected to each other by the conductive pattern 190. However, the disclosure is not limited thereto. In other embodiments, the first electrode 150 may also be electrically connected to the active device substrate 160 through other suitable components.

It should be noted that by using the first electrode 150 covering at least one portion of the side wall 110c of the first semiconductor layer 110, the light emitting apparatus 100 may emit light beams L1, L2, and L3 from the front (i.e., the top surface 120a of the second semiconductor layer 120), and light extraction efficiency and/or brightness of the light emitting apparatus 100 may be enhanced. The mechanism thereof is illustrated as follows:

Generally speaking, the light beams L1, L2, and L3 emitted by the light emitting layer 130 are not transmitted in specific directions but are transmitted in all directions. In other words, the light beams L1, L2, and L3 emitted by the light emitting layer 130 may not be all directly emitted from the front. For example, in this embodiment, the light beam L1 that is emitted upward and has a larger angle with respect to the optical axis (e.g., an axis parallel to the z direction) may not be directly emitted from the top surface 120a of the second semiconductor layer 120. However, via a portion of the first electrode 150 located on the side wall 120c of the second semiconductor layer 120, the light beam L1 may be reflected to the top surface 120a so as to be emitted from the front (i.e., the top surface 120a). Similarly, the light beam L2 that is emitted downward and has a larger angle with respect to the optical axis may not be directly emitted from the top surface 120a of the second semiconductor layer 120. However, a portion of the first electrode 150 located on the side wall 110c of the first semiconductor layer 110 may reflect the light beam L2 to a portion of the first electrode 150 located on the bottom surface 110b of the first semiconductor layer 110, and the portion of the first electrode 150 located on the bottom surface 110b of the first semiconductor layer 110 may reflect the light beam L2 to the top surface 120a of the second semiconductor layer 120, so that the light beam L2 is emitted from the front. The light beam L3 emitted to the second electrode 180 (here the second electrode 180 is exemplified to be a reflective electrode) is reflected by the second electrode 180 such that the light beam L3 may not be directly emitted from the top surface 120a of the second semiconductor layer 120. However, the light beam L3 reflected by the second electrode 180 is then transmitted to the portion of the first electrode 150 located on the bottom surface 110b of the first semiconductor layer 110 and then reflected by the portion of the first electrode 150 so as to be emitted from the front. Accordingly, light extraction efficiency and/or brightness of the light emitting apparatus 100 in this embodiment may be enhanced.

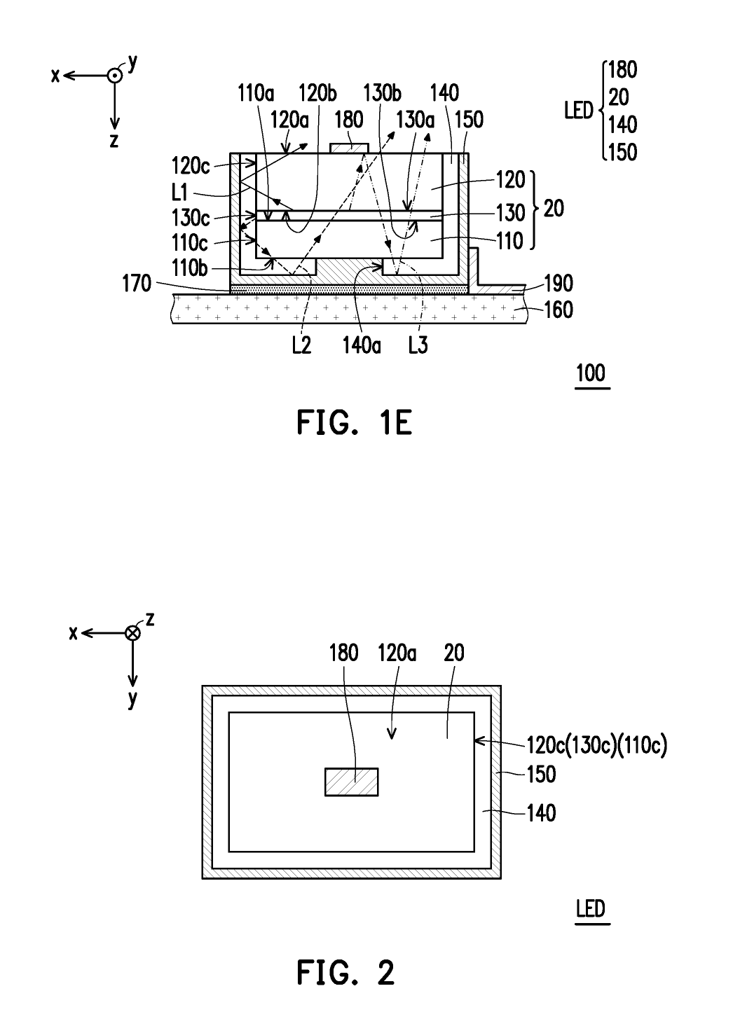

FIG. 3 is a schematic cross-sectional view of a light emitting apparatus according to another embodiment of the disclosure. Please refer to FIG. 2 for a schematic top view of the light emitting apparatus of FIG. 3. With reference to FIG. 3, a light emitting apparatus 200 is similar to the foregoing light emitting apparatus 100. Therefore, the same or similar components are assigned with the same or similar reference numerals. The main difference between the light emitting apparatus 200 and the light emitting apparatus 100 lies in that the cover range of a first electrode 152 of the light emitting apparatus 200 is different from the cover range of the first electrode 150 of the light emitting apparatus 100. The following paragraphs primarily elaborate on this difference. Please refer to the forgoing description for the same or similar parts of the two apparatuses.

With reference to FIG. 3, the light emitting apparatus 200 includes a first semiconductor layer 110, a light emitting layer 130, a second semiconductor layer 120, an insulation layer 140, the first electrode 152, and a second electrode 180. The light emitting layer 130 is disposed on the first semiconductor layer 110. The second semiconductor layer 120 is disposed on the light emitting layer 130. The light emitting layer 130 has a bottom surface 130b, a top surface 130a, and a side wall 130c. The side wall 130c of the light emitting layer 130 is connected between the bottom surface 130b of the light emitting layer 130 and the top surface 130a of the light emitting layer 130. The first semiconductor layer 110 has a bottom surface 110b, a top surface 110a, and a side wall 110c. The side wall 110c of the first semiconductor layer 110 is connected between the bottom surface 110b of the first semiconductor layer 110 and the top surface 110a of the first semiconductor layer 110. The top surface 110a of the first semiconductor layer 110 is disposed between the bottom surface 110b of the first semiconductor layer 110 and the bottom surface 130b of the light emitting layer 130. The insulation layer 140 is at least disposed on the side wall 110c of the first semiconductor layer 110. The first electrode 152 is disposed on the bottom surface 110b of the first semiconductor layer 110 and at least one portion of the insulation layer 140, and covers at least one portion of the side wall 110c of the first semiconductor layer 110. The second electrode 180 is disposed on the second semiconductor layer 120.

In this embodiment, the first electrode 152 of the light emitting apparatus 200 may completely cover the side wall 130c of the light emitting layer 130 and the side wall 110c of the first semiconductor layer 110. More specifically, the first electrode 152 surrounds the side wall 130c of the light emitting layer 130, the side wall 110c of the first semiconductor layer 110, and a side wall 120c of the second semiconductor layer 120. Here, the difference from the light emitting apparatus 100 is that the first electrode 152 covers the side wall 120c of the second semiconductor layer 120 only partially without covering the portion of the side wall 120c of the second semiconductor layer 120 closer to the second electrode 180. Besides, in this embodiment, the insulation layer 140 has a sidewall of an end portion 140b, which is selectively not covered by the first electrode 152.

With reference to FIG. 3, similarly, in this embodiment, light beams L1, L2, and L3 emitted by the light emitting layer 130 of the light emitting apparatus 200 likewise are not transmitted in specific directions but are transmitted in all directions. In other words, the light beams L1, L2, and L3 emitted by the light emitting layer 130 may not be all directly emitted from the front. For example, in this embodiment, the light beam L1 that is emitted upward and has a larger angle with respect to the optical axis (e.g., an axis parallel to the z direction) may not be directly emitted from the top surface 120a of the second semiconductor layer 120. However, via a portion of the first electrode 152 located on the side wall 120c of the second semiconductor layer 120, the light beam L1 may be reflected to the top surface 120a so as to be emitted from the front (i.e., the top surface 120a). Similarly, the light beam L2 that is emitted downward and has a larger angle with respect to the optical axis may not be directly emitted from the top surface 120a of the second semiconductor layer 120. However, a portion of the first electrode 152 located on the side wall 110c of the first semiconductor layer 110 may reflect the light beam L2 to a portion of the first electrode 150 located on the bottom surface 110b of the first semiconductor layer 110, and the portion of the first electrode 152 located on the bottom surface 110b of the first semiconductor layer 110 may then reflect the light beam L2 to the top surface 120a of the second semiconductor layer 120, so that the light beam L2 is emitted from the front. In addition, here the difference from the foregoing light emitting apparatus 100 is that the second electrode 180 in this embodiment may be a transparent electrode, and the light beam L3 emitted to the second electrode 180 may pass through the second electrode 180 so as to be emitted from the second electrode 180. Accordingly, light extraction efficiency and/or brightness of the light emitting apparatus 200 in this embodiment may be enhanced. The light emitting apparatus 200 has effects and advantages similar to those of the light emitting apparatus 100, and details thereof are not repeated here.

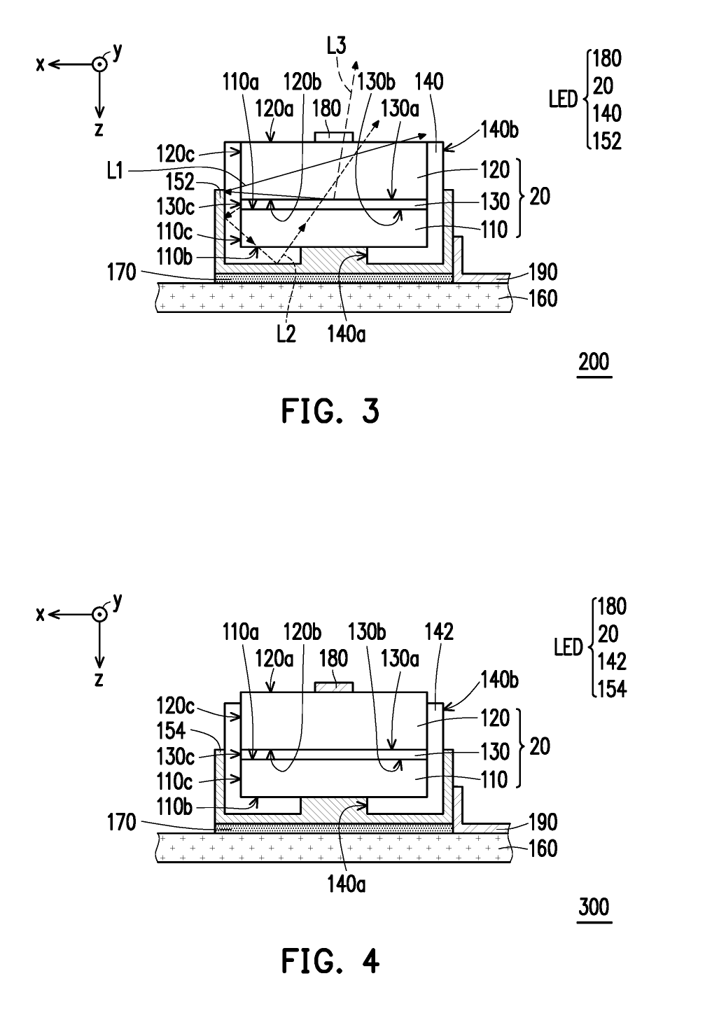

FIG. 4 is a schematic cross-sectional view of a light emitting apparatus according to yet another embodiment of the disclosure. Please refer to FIG. 2 for a schematic top view of the light emitting apparatus of FIG. 4. With reference to FIG. 4, a light emitting apparatus 300 is similar to the foregoing light emitting apparatus 100. Therefore, the same or similar components are assigned with the same or similar reference numerals. The main difference between the light emitting apparatus 300 and the light emitting apparatus 100 lies in that the cover ranges of an insulation layer 142 and a first electrode 154 of the light emitting apparatus 300 are different from the cover ranges of the insulation layer 140 and the first electrode 150 of the light emitting apparatus 100. The following paragraphs primarily elaborate on this difference. Please refer to the forgoing description for the same or similar parts of the two apparatuses.

With reference to FIG. 4, the light emitting apparatus 300 includes a first semiconductor layer 110, a light emitting layer 130, a second semiconductor layer 120, the insulation layer 142, the first electrode 154, and a second electrode 180. The light emitting layer 130 is disposed on the first semiconductor layer 110. The second semiconductor layer 120 is disposed on the light emitting layer 130. The light emitting layer 130 has a bottom surface 130b, a top surface 130a, and a side wall 130c. The side wall 130c of the light emitting layer 130 is connected between the bottom surface 130b of the light emitting layer 130 and the top surface 130a of the light emitting layer 130. The first semiconductor layer 110 has a bottom surface 110b, a top surface 110a, and a side wall 110c. The side wall 110c of the first semiconductor layer 110 is connected between the bottom surface 110b of the first semiconductor layer 110 and the top surface 110a of the first semiconductor layer 110. The top surface 110a of the first semiconductor layer 110 is disposed between the bottom surface 110b of the first semiconductor layer 110 and the bottom surface 130b of the light emitting layer 130. The insulation layer 142 is at least disposed on the side wall 110c of the first semiconductor layer 110. The first electrode 154 is disposed on the bottom surface 110b of the first semiconductor layer 110 and at least one portion of the insulation layer 142, and covers at least one portion of the side wall 110c of the first semiconductor layer 110. The second electrode 180 is disposed on the second semiconductor layer 120.

Here, the difference from the light emitting apparatus 100 is that the insulation layer 142 covers a side wall 120c of the second semiconductor layer 120 only partially without covering the portion of the side wall 120c of the second semiconductor layer 120 closer to the second electrode 180. In addition, the first electrode 154 covers the side wall 110c of the first semiconductor layer 110 and the side wall 130c of the light emitting layer 130 without covering the side wall 120c of the second semiconductor layer 120. More specifically, the first electrode 154 surrounds the side wall 110c of the first semiconductor layer 110 and the side wall 130c of the light emitting layer 130 without surrounding the side wall 120c of the second semiconductor layer 120. The light emitting apparatus 300 has effects and advantages similar to those of the light emitting apparatus 100, and details thereof are not repeated here.

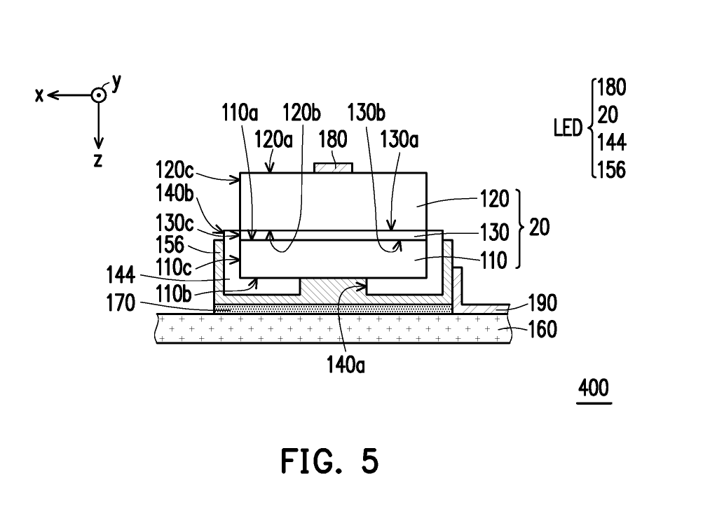

FIG. 5 is a schematic cross-sectional view of a light emitting apparatus according to an embodiment of the disclosure. Please refer to FIG. 2 for a schematic top view of the light emitting apparatus of FIG. 5. With reference to FIG. 5, a light emitting apparatus 400 is similar to the foregoing light emitting apparatus 100. Therefore, the same or similar components are assigned with the same or similar reference numerals. The main difference between the light emitting apparatus 400 and the light emitting apparatus 100 lies in that the cover ranges of an insulation layer 144 and a first electrode 156 of the light emitting apparatus 400 are different from the cover ranges of the insulation layer 140 and the first electrode 150 of the light emitting apparatus 100. The following paragraphs primarily elaborate on this difference. Please refer to the forgoing description for the same or similar parts of the two apparatuses.

With reference to FIG. 5, the light emitting apparatus 400 includes a first semiconductor layer 110, a light emitting layer 130, a second semiconductor layer 120, the insulation layer 144, the first electrode 156, and a second electrode 180. The light emitting layer 130 is disposed on the first semiconductor layer 110. The second semiconductor layer 120 is disposed on the light emitting layer 130. The light emitting layer 130 has a bottom surface 130b, a top surface 130a, and a side wall 130c. The side wall 130c of the light emitting layer 130 is connected between the bottom surface 130b of the light emitting layer 130 and the top surface 130a of the light emitting layer 130. The first semiconductor layer 110 has a bottom surface 110b, a top surface 110a, and a side wall 110c. The side wall 110c of the first semiconductor layer 110 is connected between the bottom surface 110b of the first semiconductor layer 110 and the top surface 110a of the first semiconductor layer 110. The top surface 110a of the first semiconductor layer 110 is disposed between the bottom surface 110b of the first semiconductor layer 110 and the bottom surface 130b of the light emitting layer 130. The insulation layer 144 is at least disposed on the side wall 110c of the first semiconductor layer 110. The first electrode 156 is disposed on the bottom surface 110b of the first semiconductor layer 110 and at least one portion of the insulation layer 144, and covers at least one portion of the side wall 110c of the first semiconductor layer 110. The second electrode 180 is disposed on the second semiconductor layer 120.

Here, the difference from the light emitting apparatus 100 is that the first electrode 144 in this embodiment may cover the side wall 110c of the first semiconductor layer 110 and the side wall 130c of the light emitting layer 130 without covering a side wall 120c of the second semiconductor layer 120. More specifically, the insulation layer 144 may surround the side wall 110c of the first semiconductor layer 110 and the side wall 130c of the light emitting layer 130 without surrounding the side wall 120c of the second semiconductor layer 120. In addition, in this embodiment, the first electrode 156 covers the side wall 110c of the first semiconductor layer 110 without covering the side wall 130c of the light emitting layer 130 and the side wall 120c of the second semiconductor layer 120. More specifically, the first electrode 156 surrounds the side wall 110c of the first semiconductor layer 110 without surrounding the side wall 130c of the light emitting layer 130 and the side wall 120c of the second semiconductor layer 120. The light emitting apparatus 400 has effects and advantages similar to those of the light emitting apparatus 100, and details thereof are not repeated here.

In summary, according to an embodiment of the disclosure, the light emitting apparatus includes the first semiconductor layer, the light emitting layer disposed on the first semiconductor layer, the second semiconductor layer disposed on the light emitting layer, the insulation layer at least disposed on the side wall of the first semiconductor layer, the first electrode disposed on the bottom surface of the first semiconductor layer and at least one portion of the insulation layer, and the second electrode. The light beam emitted by the light emitting layer is reflected by the first electrode so as to be emitted from the top surface (i.e., the front) of the second semiconductor layer. Accordingly, light extraction efficiency and/or brightness of the light emitting apparatus are enhanced.

Although the embodiments are already disclosed as above, these embodiments should not be construed as limitations on the scope of the disclosure. It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A light emitting apparatus, comprising:
a first semiconductor layer;
a light emitting layer disposed on the first semiconductor layer;
a second semiconductor layer disposed on the light emitting layer, wherein the light emitting layer has a bottom surface, a top surface and a side wall, the side wall of the light emitting layer is connected between the bottom surface of the light emitting layer and the top surface of the light emitting layer, the first semiconductor layer has a bottom surface, a top surface and a side wall, the side wall of the first semiconductor layer is connected between the bottom surface of the first semiconductor layer and the top surface of the first semiconductor layer, and the top surface of the first semiconductor layer is disposed between the bottom surface of the first semiconductor layer and the bottom surface of the light emitting layer;
an insulation layer at least disposed on the side wall of the first semiconductor layer;
a first electrode disposed on the bottom surface of the first semiconductor layer and at least one portion of the insulation layer, wherein the first electrode covers at least one portion of the side wall of the first semiconductor layer;
a second electrode disposed on the second semiconductor layer;
a conductive pattern, disposed on the first electrode covering at least part of the side wall of the first semiconductor layer; and
an active device substrate, wherein the first electrode is electrically connected to the active device substrate through the conductive pattern.

2. The light emitting apparatus as recited in claim 1, wherein the first electrode surrounds the at least one portion of the side wall of the first semiconductor layer.

3. The light emitting apparatus as recited in claim 1, wherein the insulation layer is disposed on the side wall of the first semiconductor layer and the side wall of the light emitting layer, and the first electrode further covers at least one portion of the side wall of the light emitting layer.

4. The light emitting apparatus as recited in claim 3, wherein the first electrode surrounds the side wall of the first semiconductor layer and the at least one portion of the side wall of the light emitting layer.

5. The light emitting apparatus as recited in claim 1, wherein the second semiconductor layer has a bottom surface, a top surface and a side wall, the side wall of the second semiconductor layer is connected between the bottom surface of the second semiconductor layer and the top surface of the second semiconductor layer, and the insulation layer is disposed on the side wall of the first semiconductor layer, the side wall of the light emitting layer and at least one portion of the side wall of the second semiconductor layer.

6. The light emitting apparatus as recited in claim 5, wherein the first electrode further covers the side wall of the light emitting layer and a portion of the side wall of the second semiconductor layer.

7. The light emitting apparatus as recited in claim 5, wherein the first electrode surrounds the side wall of the first semiconductor layer, the side wall of the light emitting layer, and a portion of the side wall of the second semiconductor layer.

8. The light emitting apparatus as recited in claim 1, wherein the insulation layer further partially covers the bottom surface of the first semiconductor layer.

9. The light emitting apparatus as recited in claim 1, wherein the insulation layer further covers the bottom surface of the first semiconductor layer and has a contact hole located on the bottom surface of the first semiconductor layer, and the first electrode is filled in the contact hole of the insulation layer to be electrically connected to the first semiconductor layer.

10. The light emitting apparatus as recited in claim 1, wherein a sidewall of an end portion of the insulation layer is not covered by the first electrode.

11. The light emitting apparatus as recited in claim 1, further comprising:
an active device substrate, wherein the first electrode is electrically connected to the active device substrate.

12. The light emitting apparatus as recited in claim 11, further comprising:
a conductive pattern, wherein the first electrode is electrically connected to the active device substrate through the conductive pattern, and the conductive pattern and the second electrode are made of a same material.

13. The light emitting apparatus as recited in claim 1, further comprising a bonding layer, so as to fix the first electrode on the active device substrate.
